(19) United States
(12) Patent Application Publication
(10) Pub. No.: US 2018/0018219 A1
(43) Pub. Date: Jan. 18, 2018

(54) SEMICONDUCTOR DEVICES AND SEMICONDUCTOR SYSTEMS

(71) Applicant: SK hynix Inc., Icheon-si Gyeonggi-do (KR)

(72) Inventors: Chang Hyun KIM, Seoul (KR); Do Yun LEE, Yongin-si Gyeonggi-do (KR)

(73) Assignee: SK hynix Inc., Icheon-si Gyeonggi-do (KR)

(21) Appl. No.: 15/428,856

(22) Filed: Feb. 9, 2017

(30) Foreign Application Priority Data
Jul. 18, 2016 (KR) 1020160090501

(51) Int. Cl. G06F 11/10; G11C 7/12; G11C 7/22; G11C 7/10; G11C 29/52; G11C 8/06

(52) U.S. Cl. CPC G06F 11/106; G11C 29/52; G11C 8/06; G11C 7/22; G06F 11/1068; G11C 7/1012; G11C 7/10; G11C 7/12

(57) ABSTRACT

A semiconductor system including a first semiconductor device and a second semiconductor device may be provided. The first semiconductor device may be configured to outputs commands and addresses. The first semiconductor device may be configured to output or receive data. The second semiconductor device may be configured to store addresses of output data having an erroneous bit and the output data in memory cells during a read operation and perform an error scrub operation.

### CROSS-REFERENCE TO RELATED APPLICATIONS

The present application claims priority under 35 U.S.C 119(a) to Korean Patent Application No. 10-2016-0090501, filed on Jul. 18, 2016, which is incorporated herein by reference in its entirety.

### BACKGROUND

### 1. Technical Field

Embodiments of the present disclosure may generally relate semiconductor devices configured to perform an error scrub operation and semiconductor systems employing the semiconductor devices.

### 2. Related Art

Semiconductor devices may be designed and fabricated to include a test mode function for evaluating the operations thereof. That is, various parameters of the semiconductor devices may be measured in a test mode at a wafer level or at a package level. The tested semiconductor devices may be sorted into good chips or failed chips according to the test results.

Each of the semiconductor devices may perform a write operation and a read operation to receive and output a plurality of data through pads. Each semiconductor device may be evaluated by comparing and sensing logic levels of the data outputted from the pads.

As the semiconductor devices become more highly integrated with the development of fabrication process techniques, the number of failed memory cells in the tested semiconductor devices has been increasing. An increase in the number of failed memory cells within the tested semiconductor devices may lead to not only a reduction in the production yield of the semiconductor devices but also difficulty in guaranteeing a large memory capacity for the semiconductor devices. Accordingly, error correction code (ECC) circuits have been widely employed in the semiconductor devices to solve data errors which are due to the failed memory cells.

### SUMMARY

According to an embodiment, a semiconductor system may be provided. The semiconductor system may include a first semiconductor device and a second semiconductor device. The first semiconductor device may be configured to outputs commands and addresses. The first semiconductor device may be configured to output or receive data. The second semiconductor device may be configured to store addresses of output data having an erroneous bit and the output data in memory cells during a read operation and perform an error scrub operation.

According to an embodiment, a semiconductor device may be provided. The semiconductor device may be configured to store addresses of output data having an erroneous bit and the output data in memory cells during a read operation and perform an error scrub operation.

### BRIEF DESCRIPTION OF THE DRAWINGS

FIG. 1 is a block diagram illustrating a representation of an example of a semiconductor system according to an embodiment of the present disclosure.

FIG. 2 is a block diagram illustrating a representation of an example of an example of an error scrub control circuit included in the semiconductor system of FIG. 1.

FIG. 3 is a logic circuit diagram illustrating a representation of an example of a scrub signal generation circuit included in the error scrub control circuit of FIG. 2.

FIG. 4 is a block diagram illustrating a representation of an example of a storage circuit included in the semiconductor system of FIG. 1.

FIGS. 5 and 6 are timing diagrams illustrating representations of examples of operations of a semiconductor system according to an embodiment.

FIG. 7 is a block diagram illustrating a representation of an example of a configuration of an electronic system employing a semiconductor device or a semiconductor system illustrated in FIGS. 1 to 6.

FIG. 8 is a block diagram illustrating a representation of an example of a configuration of an electronic system employing a semiconductor device or a semiconductor system illustrated in FIGS. 1 to 6.

### DETAILED DESCRIPTION

Various embodiments of the present disclosure will be described hereinafter with reference to the accompanying drawings. However, the embodiments described herein are for illustrative purposes only and are not intended to limit the scope of the present disclosure.

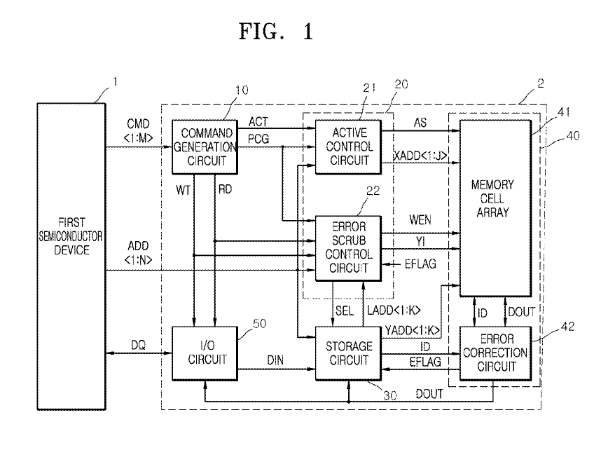

Referring to FIG. 1, a semiconductor system according to an embodiment may include a first semiconductor device 1 and a second semiconductor device 2. The second semiconductor device 2 may include a command generation circuit 10, a control circuit 20, a storage circuit 30, a memory area 40 and an input/output (I/O) circuit 50.

The first semiconductor device 1 may output first to M^{th} commands CMD<1:M> and first to N^{th} addresses ADD<1:N>. The first semiconductor device 1 may output data DQ during a write operation and may receive the data DQ during a read operation. The number “M” of bits included in the first to M^{th} commands CMD<1:M> may be set to be a natural number. The number “M” of the bits included in the first to M^{th} commands CMD<1:M> may be set to be different according to the embodiments. The number “N” of bits included in the first to N^{th} addresses ADD<1:N> may be set to be a natural number. The number “N” of the bits included in the first to N^{th} addresses ADD<1:N> may be set to be different according to the embodiments.

The command generation circuit 10 may decode the first to M^{th} commands CMD<1:M> to generate an active command ACT, a pre-charge command PCG, a read command RD and a write command WT. The command generation circuit 10 may generate the active command ACT for performing an active operation according to a combination of the first to M^{th} commands CMD<1:M>. The command generation circuit 10 may generate the pre-charge command PCG for performing a pre-charge operation according to a combination of the first to M^{th} commands CMD<1:M>. The command generation circuit 10 may generate the read command RD for performing the read operation according to a combination of the first to M^{th} commands CMD<1:M>. The command generation circuit 10 may generate the write command WT for performing the write operation according to a combination of the first to M^{th} commands CMD<1:M>.

The control circuit 20 may include an active control circuit 21 and an error scrub control circuit 22.

The active control circuit 21 may generate an active signal AS which is enabled in response to the active command ACT and the pre-charge command PCG. The active control circuit 21 may generate first to J^{th} row addresses XADD<1:J> from the first to N^{th} addresses ADD<1:N> in response to the active command ACT and the pre-charge command PCG. The number “J” of bits included in the first to J^{th} row addresses XADD<1:J> may be set to be a natural number. The number “J” of the bits included in the first to J^{th} row addresses XADD<1:J> may be set to be equal to or less than the number “N” of the bits included in the first to N^{th} addresses ADD<1:N>.

The error scrub control circuit 22 may generate an enablement signal WEN and a column selection signal YI from the first to N^{th} addresses ADD<1:N> in response to the pre-charge command PCG, the read command RD and the write command WT. The error scrub control circuit 22 may compare the first to N^{th} addresses ADD<1:N> with first to K^{th} latch addresses LADD<1:K> to generate a selection signal SEL, in response to the pre-charge command PCG and a flag signal EFLAG. Although FIG. 1 illustrates an example in which the error scrub control circuit 22 is realized to operate in response to the pre-charge command PCG, the present disclosure is not limited to the configuration of FIG. 1. For example, in some other embodiments, the error scrub control circuit 22 may be realized to operate in response to a refresh command. The number “K” of bits included in the first to K^{th} latch addresses LADD<1:K> may be set to be a natural number. The number “K” of the bits included in the first to K^{th} latch addresses LADD<1:K> may be set to be equal to or less than the number “N” of the bits included in the first to N^{th} addresses ADD<1:N>. The flag signal EFLAG may be set to be a signal including a pulse which is created if output data DOUT have a failed bit (i.e., an erroneous bit).

The control circuit 20 having an aforementioned configuration may generate the active signal AS, the first to J^{th} row addresses XADD<1:J>, the enablement signal WEN and the column selection signal YI during a predetermined operation and may compare the first to N^{th} addresses ADD<1:N> with the first to K^{th} latch addresses LADD<1:K> to generate the selection signal SEL in response to the flag signal EFLAG. The predetermined operation may be set to be the pre-charge operation or a refresh operation.

The storage circuit 30 may latch the first to N^{th} addresses ADD<1:N> to generate the first to K^{th} latch addresses LADD<1:K> in response to the flag signal EFLAG and the selection signal SEL. The storage circuit 30 may output the first to N^{th} addresses ADD<1:N> or the first to K^{th} latch addresses LADD<1:K> as first to K^{th} column addresses YADD<1:K> in response to the selection signal SEL. The storage circuit 30 may latch the output data DOUT to generate internal data ID in response to the flag signal EFLAG and the selection signal SEL. The storage circuit 30 may output input data DIN or the latched output data DOUT as the internal data ID in response to the selection signal SEL.

The memory area 40 may include a memory cell array 41 and an error correction circuit 42.

The memory cell array 41 may include a plurality of memory cells which are respectively disposed at cross points of a plurality of word lines and a plurality of bit lines. During the write operation, the memory cell array 41 may store the internal data ID in at least one memory cell which is disposed at a cross point of one word line selected in response to the active signal AS and the first to J^{th} row addresses XADD<1:J> and at least one bit line selected in response to the enablement signal WEN, the column selection signal YI and the first to K^{th} column addresses YADD<1:K>. During the read operation, the memory cell array 41 may output the internal data ID stored in at least one memory cell, which is located at a cross point of one word line selected in response to the active signal AS and the first to J^{th} row addresses XADD<1:J> and at least one bit line selected in response to the enablement signal WEN, the column selection signal YI and the first to K^{th} column addresses YADD<1:K>, as the output data DOUT. The memory cell array 41 may be realized using a nonvolatile memory device or a volatile memory device.

The error correction circuit 42 may detect errors of the output data DOUT to generate the flag signal EFLAG during the read operation. The error correction circuit 42 may correct the errors of the output data DOUT to output the corrected output data during the read operation. The error correction circuit 42 may also correct errors of the internal data ID during the write operation or the predetermined operation. The error correction circuit 42 may be realized to include a general error correction code (ECC) circuit. Although FIG. 1 illustrates an example in which the error correction circuit 42 is included in the memory area 40, the present disclosure is not limited to the configuration of FIG. 1. For example, in some other embodiments, the error correction circuit 42 may be disposed to be separate from the memory area 40.

The I/O circuit 50 may receive the data DQ from the first semiconductor device 1 and may output the data DQ as the input data DIN, in response to the write command WT during the write operation. The I/O circuit 50 may receive the output data DOUT from the memory area 40 and may output the output data DOUT as the data DQ, in response to the read command RD during the read operation.

The second semiconductor device 2 having an aforementioned configuration may correct errors of the output data DOUT to store the corrected output data and the first to N^{th} addresses ADD<1:N> therein if the errors are included in the output data DOUT to be outputted as the data DQ while the read operation is performed in response to the first to M^{th} commands CMD<1:M> and the first to N^{th} addresses ADD<1:N> and may perform an error scrub operation using the corrected and stored output data and the stored first to N^{th} addresses ADD<1:N> during the predetermined operation. The error scrub operation means an operation that restores the corrected output data in memory cells selected by the first to N^{th} addresses ADD<1:N>.

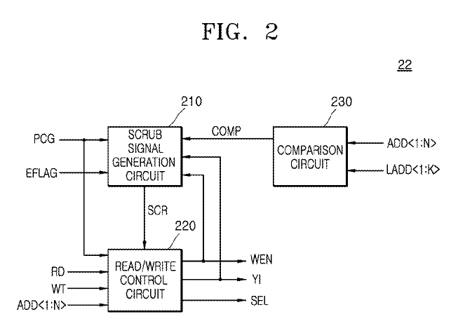

Referring to FIG. 2, the error scrub control circuit 22 may include a scrub signal generation circuit 210, a read/write control circuit 220 and a comparison circuit 230.

The scrub signal generation circuit 210 may generate a scrub signal SCR which is enabled during a predetermined period in response to the pre-charge command PCG and the flag signal EFLAG and which is disabled in response to the enablement signal WEN, the column selection signal YI and a comparison signal COM. The scrub signal generation circuit 210 may generate the scrub signal SCR which is enabled if the pre-charge command PCG is inputted and the pulse of the flag signal EFLAG is inputted. The scrub signal generation circuit 210 may generate the scrub signal SCR which is disabled after the predetermined period from a point of time that the scrub signal SCR is enabled. The scrub signal generation circuit 210 may generate the scrub signal SCR which is disabled if the enablement signal WEN, the column selection signal YI and the comparison signal COMP are enabled.

The read/write control circuit 220 may generate the selection signal SEL which is enabled if the scrub signal SCR is enabled, in response to the pre-charge command PCG, the write command WT and the read command RD and may generate the enablement signal WEN and the column selection signal YI according to a combination of the first to N^{th} addresses ADD<1:N>. The read/write control circuit 220 may generate the selection signal SEL which is enabled if the scrub signal SCR is enabled during the predetermined operation. The read/write control circuit 220 may generate the enablement signal WEN and the column selection signal YI according to a combination of the first to N^{th} addresses ADD<1:N> during the read operation, the write operation or the predetermined operation. The read/write control circuit 220 may generate the selection signal SEL which is enabled if the pre-charge command PCG is inputted and a pulse of the scrub signal SCR is inputted. The read/write control circuit 220 may generate the enablement signal WEN and the column selection signal YI according to a combination of the first to N^{th} addresses ADD<1:N> if any one of the pre-charge command PCG, the write command WT and the read command RD is inputted. The enablement signal WEN may be enabled according to a combination of the first to N^{th} addresses ADD<1:N> if the pre-charge command PCG and the write command WT are inputted and may be set to operate drivers for writing data into memory cells. Although FIG. 2 illustrates the enablement signal WEN with a single signal line, the enablement signal WEN may include a plurality of signals. The column selection signal YI may be enabled according to a combination of the first to N^{th} addresses ADD<1:N> if any one of the pre-charge command PCG, the write command WT and the read command RD is inputted and may be set to operate switches connected to memory cells. Although FIG. 2 illustrates the column selection signal YI with a single signal line, the column selection signal YI may include a plurality of signals.

The comparison circuit 230 may compare the first to N^{th} addresses ADD<1:N> with the first to K^{th} latch addresses LADD<1:K> to generate the comparison signal COM. The comparison circuit 230 may generate the comparison signal COM which is enabled if a combination of the first to N^{th} addresses ADD<1:N> is consistent with a combination of the first to K^{th} latch addresses LADD<1:K>. A logic level of the enabled comparison signal COM may be set to be different according to the embodiments.

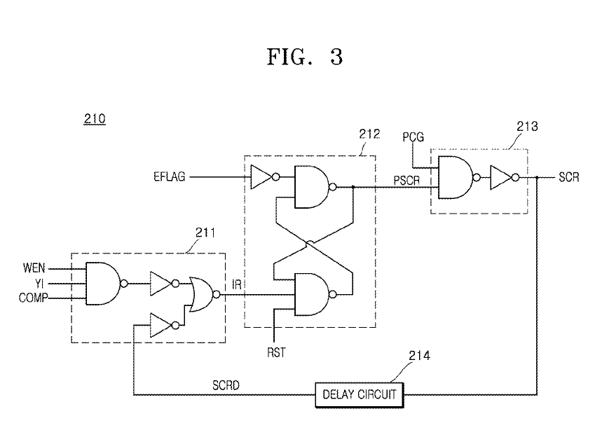

Referring to FIG. 3, the scrub signal generation circuit 210 may include a first logic circuit 211, a latch circuit 212, a second logic circuit 213 and a delay circuit 214.

The first logic circuit 211 may generate an internal reset signal IR which is enabled in response to the enablement signal WEN, the column selection signal YI and the comparison signal COMP or in response to a delayed scrub signal SCRD. The first logic circuit 211 may generate the internal reset signal IR which is enabled to have a logic “low” level if the enablement signal WEN having a logic “high” level, the column selection signal YI having a logic “high” level, and the comparison signal COM having a logic “high” level are inputted. The first logic circuit 211 may generate the internal reset signal IR which is enabled to have a logic “low” level if the delayed scrub signal SCRD having a logic “low” level is inputted. Further, the logic levels of the signals may be different from or the opposite of those described. For example, a signal described as having a logic “high” level may alternatively have a logic “low” level, and a signal described as having a logic “low” level may alternatively have a logic “high” level.

The latch circuit 212 may generate a pre-scrub signal PSCR which is enabled in response to the flag signal EFLAG and which is disabled in response to the internal reset signal IR or an external reset signal RST. The latch circuit 212 may generate the pre-scrub signal PSCR which is enabled to have a logic “high” level if the flag signal EFLAG having a logic “high” level is inputted. The latch circuit 212 may generate the pre-scrub signal PSCR which is disabled to have a logic “low” level if the internal reset signal IR having a logic “low” level or the external reset signal RST having a logic “low” level is inputted. The external reset signal RST may be provided from an external device to initialize the latch circuit 212. Further, the logic levels of the signals may be different from or the opposite of those described. For example, a signal described as having a logic “high” level may alternatively have a logic “low” level, and a signal described as having a logic “low” level may alternatively have a logic “high” level.

The second logic circuit 213 may output the pre-scrub signal PSCR as the scrub signal SCR in response to the pre-charge command PCG. The second logic circuit 213 may output the pre-scrub signal PSCR as the scrub signal SCR if the pre-charge command PCG having a logic “high” level is inputted. The second logic circuit 213 may generate the scrub signal SCR which is disabled to have a logic “low” level if the pre-charge command PCG is not inputted to the second logic circuit 213. Further, the logic levels of the signals may be different from or the opposite of those described. For example, a signal described as having a logic “high” level may alternatively have a logic “low” level, and a signal described as having a logic “low” level may alternatively have a logic “high” level.

The delay circuit 214 may delay the scrub signal SCR by a predetermined delay time to generate the delayed scrub signal SCRD. For example, the delay circuit 214 may delay the scrub signal SCR by the predetermined delay time and may inversely buffer the delayed scrub signal to generate the delayed scrub signal SCRD. The predetermined delay time of the delay circuit 214 may be set to be different according to the embodiments.

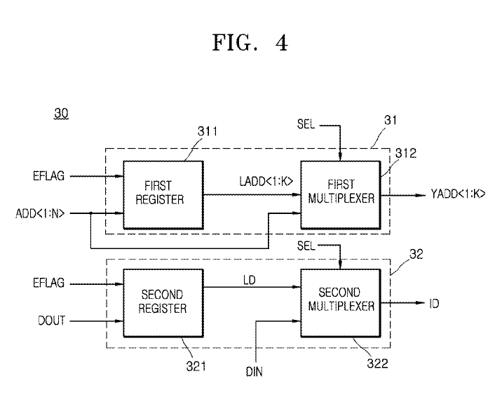

Referring to FIG. 4, the storage circuit 30 may include an address storage circuit 31 and a data storage circuit 32.

The address storage circuit 31 may include a first register 311 and a first multiplexer 312.

The first register 311 may latch the first to N^{th} addresses ADD<1:N> to generate the first to K^{th} latch addresses LADD<1:K> in response to the flag signal EFLAG. The first register 311 may latch the first to N^{th} addresses ADD<1:N> to generate the first to K^{th} latch addresses LADD<1:K> if the flag signal EFLAG having a logic “high” level is inputted. The first register 311 may latch some bits of the first to N^{th} addresses ADD<1:N> to generate the first to K^{th} latch addresses LADD<1:K> if the flag signal EFLAG having a logic “high” level is inputted. Further, the logic levels of the signals may be different from or the opposite of those described. For example, a signal described as having a logic “high” level may alternatively have a logic “low” level, and a signal described as having a logic “low” level may alternatively have a logic “high” level.

The first multiplexer 312 may output the first to K^{th} latch addresses LADD<1:K> or the first to N^{th} addresses ADD<1:N> as the first to K^{th} column addresses YADD<1:K> in response to the selection signal SEL. The first multiplexer 312 may output the first to K^{th} latch addresses LADD<1:K> as the first to K^{th} column addresses YADD<1:K> if the selection signal SEL having a logic “high” level is inputted. The first multiplexer 312 may output the first to N^{th} addresses ADD<1:N> as the first to K^{th} column addresses YADD<1:K> if the selection signal SEL having a logic “low” level is inputted. The first multiplexer 312 may output some bits of the first to N^{th} addresses ADD<1:N> as the first to K^{th} column addresses YADD<1:K> if the selection signal SEL having a logic “low” level is inputted. Further, the logic levels of the signals may be different from or the opposite of those described. For example, a signal described as having a logic “high” level may alternatively have a logic “low” level, and a signal described as having a logic “low” level may alternatively have a logic “high” level.

The address storage circuit 31 having an aforementioned configuration may latch the first to N^{th} addresses ADD<1:N> to generate the first to K^{th} latch addresses LADD<1:K> in response to the flag signal EFLAG and may output the first to K^{th} latch addresses LADD<1:K> or the first to N^{th} addresses ADD<1:N> as the first to K^{th} column addresses YADD<1:K> in response to the selection signal SEL.

The data storage circuit 32 may include a second register 321 and a second multiplexer 322.

The second register 321 may latch the output data DOUT to generate latch data LD in response to the flag signal EFLAG. The second register 321 may latch the output data DOUT to generate latch data LD in response to the flag signal EFLAG if the flag signal EFLAG having a logic “high” level is inputted. Further, the logic levels of the signals may be different from or the opposite of those described. For example, a signal described as having a logic “high” level may alternatively have a logic “low” level, and a signal described as having a logic “low” level may alternatively have a logic “high” level.

The second multiplexer 322 may output the latch data LD or the input data DIN as the internal data ID in response to the selection signal SEL. The second multiplexer 322 may output the latch data LD as the internal data ID if the selection signal SEL having a logic “high” level is inputted. The second multiplexer 322 may output the input data DIN as the internal data ID if the selection signal SEL having a logic “low” level is inputted. Further, the logic levels of the signals may be different from or the opposite of those described. For example, a signal described as having a logic “high” level may alternatively have a logic “low” level, and a signal described as having a logic “low” level may alternatively have a logic “high” level.

The data storage circuit 32 having an aforementioned configuration may latch the output data DOUT to generate the latch data LD in response to the flag signal EFLAG and may output the latch data LD or the input data DIN as the internal data ID in response to the selection signal SEL.

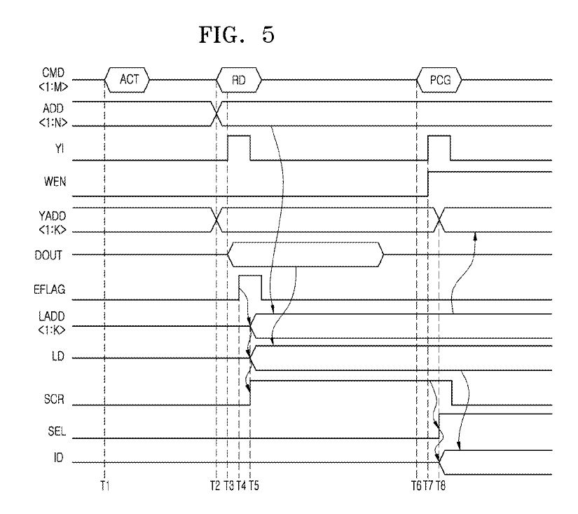

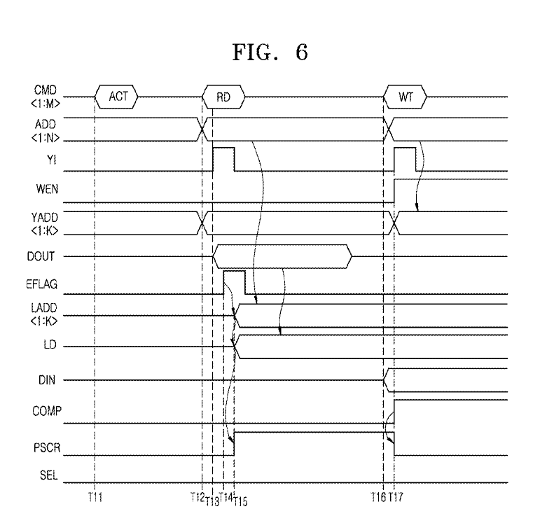

Operations of the semiconductor system illustrated in FIGS. 1 to 4 will be described hereinafter with reference to FIGS. 5 and 6 in conjunction with an example in which the error scrub operation is performed and an example in which the error scrub operation is not performed.

First, the operation of a semiconductor system will be described hereinafter in conjunction with the case that the error scrub operation is performed.

At a point of time “T1”, the first semiconductor device 1 may output the first to M^{th} commands CMD<1:M> and the first to N^{th} addresses ADD<1:N> for performing the active operation.

The command generation circuit 10 may decode the first to M^{th} commands CMD<1:M> to generate the active command ACT.

The active control circuit 21 may generate the active signal AS which is enabled in response to the active command ACT and may generate the first to J^{th} row addresses XADD<1:J> from the first to N^{th} addresses ADD<1:N> in response to the active command ACT.

At a point of time “T2”, the first semiconductor device 1 may output the first to M^{th} commands CMD<1:M> and the first to N^{th} addresses ADD<1:N> for performing the read operation.

The command generation circuit 10 may decode the first to M^{th} commands CMD<1:M> to generate the read command RD.

At a point of time “T3”, the error scrub control circuit 22 may generate the enablement signal WEN having a logic “low” level and the column selection signal YI having a logic “high” level from the first to N^{th} addresses ADD<1:N> in response to the read command RD.

The storage circuit 30 may output the first to N^{th} addresses ADD<1:N> as the first to K^{th} column addresses YADD<1:K> in response to the selection signal SEL having a logic “low” level.

During the read operation, the memory cell array 41 may output the internal data ID stored in at least one memory cell, which is located at a cross point of one word line selected in response to the active signal AS and the first to J^{th} row addresses XADD<1:J> and at least one bit line selected in response to the column selection signal YI and the first to K^{th} column addresses YADD<1:K>, as the output data DOUT. In such a case, it is assumed that the output data DOUT include an erroneous bit.

At a point of time “T4”, the error correction circuit 42 may detect the erroneous bit of the output data DOUT to generate a pulse of the flag signal EFLAG and may correct the erroneous bit of the output data DOUT.

At a point of time “T5”, the scrub signal generation circuit 210 of the error scrub control circuit 22 may generate the scrub signal SCR which is enabled if the pre-charge command PCG is inputted and the pulse of the flag signal EFLAG is inputted.

The storage circuit 30 may latch the first to N^{th} addresses ADD<1:N> to generate the first to K^{th} latch addresses LADD<1:K> in response to the flag signal EFLAG having a logic “high” level. In such a case, the first to N^{th} addresses ADD<1:N> may have a combination for selecting at least one memory cell that stores the output data DOUT including the erroneous bit. The storage circuit 30 may latch the corrected output data DOUT to generate the latch data LD in response to the flag signal EFLAG having a logic “high” level.

At a point of time “T6”, the first semiconductor device 1 may output the first to M^{th} commands CMD<1:M> and the first to N^{th} addresses ADD<1:N> for performing the pre-charge operation corresponding to the predetermined operation.

The command generation circuit 10 may decode the first to M^{th} commands CMD<1:M> to generate the pre-charge command PCG.

The active control circuit 21 may generate the active signal AS which is enabled in response to the pre-charge command PCG and may generate the first to J^{th} row addresses XADD<1:J> from the first to N^{th} addresses ADD<1:N> in response to the pre-charge command PCG.

At a point of time “T7”, the read/write control circuit 220 of the error scrub control circuit 22 may generate the enablement signal WEN having a logic “high” level and the column selection signal YI having a logic “high” level from the first to N^{th} addresses ADD<1:N> in response to the pre-charge command PCG.

At a point of time “T8”, the read/write control circuit 220 of the error scrub control circuit 22 may generate the selection signal SEL which is enabled to have a logic “high” level in response to the scrub signal SCR having a logic “high” level during the pre-charge operation corresponding to the predetermined operation.

The storage circuit 30 may output the first to K^{th} latch addresses LADD<1:K> as the first to K^{th} column addresses YADD<1:K> in response to the selection signal SEL having a logic “high” level. The storage circuit 30 may output the latch data LD corresponding to the corrected output data DOUT as the internal data ID in response to the selection signal SEL having a logic “high” level.

The memory cell array 41 may store the internal data ID in at least one memory cell which is located at a cross point of one word line selected in response to the first to J^{th} row addresses XADD<1:J> and at least one bit line selected in response to the enablement signal WEN, the column selection signal YI and the first to K^{th} column addresses YADD<1:K>.

As described above, the semiconductor system according to an embodiment may store addresses of output data having an erroneous bit and the output data in memory cells during a read operation and may perform an error scrub operation that restores the stored output data in the memory cells during a predetermined operation, thereby generating the output data without any error.

Next, the operation of the semiconductor system will be described hereinafter in conjunction with the case that the error scrub operation is not performed.

At a point of time “T11”, the first semiconductor device 1 may output the first to M^{th} commands CMD<1:M> and the first to N^{th} addresses ADD<1:N> for performing the active operation.

The command generation circuit 10 may decode the first to M^{th} commands CMD<1:M> to generate the active command ACT.

The active control circuit 21 may generate the active signal AS which is enabled in response to the active command ACT and may generate the first to J^{th} row addresses XADD<1:3> from the first to N^{th} addresses ADD<1:N> in response to the active command ACT.

At a point of time “T12”, the first semiconductor device 1 may output the first to M^{th} commands CMD<1:M> and the first to N^{th} addresses ADD<1:N> for performing the read operation.

The command generation circuit 10 may decode the first to M^{th} commands CMD<1:M> to generate the read command RD.

At a point of time “T13”, the error scrub control circuit 22 may generate the enablement signal WEN having a logic “low” level and the column selection signal YI having a logic “high” level from the first to N^{th} addresses ADD<1:N> in response to the read command RD.

The storage circuit 30 may output the first to N^{th} addresses ADD<1:N> as the first to K^{th} column addresses YADD<1:K> in response to the selection signal SEL having a logic “low” level.

During the read operation, the memory cell array 41 may output the internal data ID stored in at least one memory cell, which is located at a cross point of one word line selected in response to the active signal AS and the first to J^{th} row addresses XADD<1:J> and at least one bit line selected in response to the column selection signal YI and the first to K^{th} column addresses YADD<1:K>, as the output data DOUT. In such a case, it is assumed that the output data DOUT include an erroneous bit.

At a point of time “T14”, the error correction circuit 42 may detect the erroneous bit of the output data DOUT to generate a pulse of the flag signal EFLAG and may correct the erroneous bit of the output data DOUT.

At a point of time “T15”, the storage circuit 30 may latch the first to N^{th} addresses ADD<1:N> to generate the first to K^{th} latch addresses LADD<1:K> in response to the flag signal EFLAG having a logic “high” level. In such a case, the first to N^{th} addresses ADD<1:N> may have a combination for selecting at least one memory cell that stores the output data DOUT including the erroneous bit. The storage circuit 30 may latch the corrected output data DOUT to generate the latch data LD in response to the flag signal EFLAG having a logic “high” level.

The scrub signal generation circuit 210 of the error scrub control circuit 22 may generate the pre-scrub signal PSCR which is enabled to have a logic “high” level in response to a pulse of the flag signal EFLAG.

At a point of time “T16”, the first semiconductor device 1 may output the first to M^{th} commands CMD<1:M> and the first to N^{th} addresses ADD<1:N> for performing the write operation. The first semiconductor device 1 may also output the data DQ.

The command generation circuit 10 may decode the first to M^{th} commands CMD<1:M> to generate the write command WT.

The I/O circuit 50 may receive the data DQ and may output the data DQ as the input data DIN, in response to the write command WT.

At a point of time “T17”, the read/write control circuit 220 of the error scrub control circuit 22 may generate the enablement signal WEN having a logic “high” level and the column selection signal YI having a logic “high” level from the first to N^{th} addresses ADD<1:N> in response to the write command WT.

The comparison circuit 230 of the error scrub control circuit 22 may compare the first to N^{th} addresses ADD<1:N> with the first to K^{th} latch addresses LADD<1:K> to generate the comparison signal COM having a logic “high” level. In such a case, the first to N^{th} addresses ADD<1:N> may have a combination for selecting at least one memory cell that stores the output data DOUT including the erroneous bit.

The scrub signal generation circuit 210 of the error scrub control circuit 22 may generate the pre-scrub signal PSCR having a logic “low” level in response to the enablement signal WEN having a logic “high” level, the column selection signal YI having a logic “high” level, and the comparison signal COM having a logic “high” level. In such a case, a pulse of the scrub signal SCR is not generated.

The read/write control circuit 220 of the error scrub control circuit 22 may generate the selection signal SEL having a logic “low” level in response to the write command WT because a pulse of the scrub signal SCR is not inputted.

The storage circuit 30 may output the first to N^{th} addresses ADD<1:N> as the first to K^{th} column addresses YADD<1:K> in response to the selection signal SEL having a logic “low” level. The storage circuit 30 may output the input data DIN as the internal data ID in response to the selection signal SEL having a logic “low” level.

The memory cell array 41 may store the internal data ID in at least one memory cell which is located at a cross point of one word line selected in response to the first to J^{th} row addresses XADD<1:J> and at least one bit line selected in response to the enablement signal WEN, the column selection signal YI and the first to K^{th} column addresses YADD<1:K>.

As described above, the semiconductor system according to an embodiment may store addresses of output data having an erroneous bit and the output data during a read operation and may not perform an error scrub operation if memory cells storing the output data having an erroneous bit are selected during a write operation.

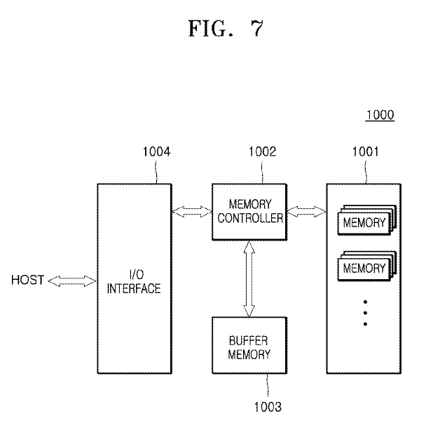

The semiconductor devices or the semiconductor systems described with reference to FIGS. 1 to 6 may be applied to an electronic system that includes a memory system, a graphic system, a computing system, a mobile system, or the like. For example, referring to FIG. 7, an electronic system 1000 according an embodiment may include a data storage circuit 1001, a memory controller 1002, a buffer memory 1003, and an input/output (I/O) interface 1004.

The data storage circuit 1001 may store data which are outputted from the memory controller 1002 or may read and output the stored data to the memory controller 1002, according to a control signal generated from the memory controller 1002. The data storage circuit 1001 may include the second semiconductor device 2 illustrated in FIG. 1. The data storage circuit 1001 may include a nonvolatile memory that can retain their stored data even when its power supply is interrupted. The nonvolatile memory may be a flash memory such as a NOR-type flash memory or a NAND-type flash memory, a phase change random access memory (PRAM), a resistive random access memory (RRAM), a spin transfer torque random access memory (STTRAM), a magnetic random access memory (MRAM), or the like.

The memory controller 1002 may receive a command outputted from an external device (e.g., a host device) through the I/O interface 1004 and may decode the command outputted from the host device to control an operation for inputting data into the data storage circuit 1001 or the buffer memory 1003 or for outputting the data stored in the data storage circuit 1001 or the buffer memory 1003. Although FIG. 7 illustrates the memory controller 1002 with a single block, the memory controller 1002 may include one controller for controlling the data storage circuit 1001 comprised of a nonvolatile memory and another controller for controlling the buffer memory 1003 comprised of a volatile memory.

The buffer memory 1003 may temporarily store the data which are processed by the memory controller 1002. That is, the buffer memory 1003 may temporarily store the data which are outputted from or to be inputted to the data storage circuit 1001. The buffer memory 1003 may store the data, which are outputted from the memory controller 1002, according to a control signal. The buffer memory 1003 may read and output the stored data to the memory controller 1002. The buffer memory 1003 may include a volatile memory such as a dynamic random access memory (DRAM), a mobile DRAM, or a static random access memory (SRAM).

The I/O interface 1004 may physically and electrically connect the memory controller 1002 to the external device (i.e., the host). Thus, the memory controller 1002 may receive control signals and data supplied from the external device (i.e., the host) through the I/O interface 1004 and may output the data generated from the memory controller 1002 to the external device (i.e., the host) through the I/O interface 1004. That is, the electronic system 1000 may communicate with the host through the I/O interface 1004. The I/O interface 1004 may include any one of various interface protocols such as a universal serial bus (USB), a multi-media card (MMC), a peripheral component interconnect-express (PCI-E), a serial attached SCSI (SAS), a serial AT attachment (SATA), a parallel AT attachment (PATA), a small computer system interface (SCSI), an enhanced small device interface (ESDI) and an integrated drive electronics (IDE).

The electronic system 1000 may be used as an auxiliary storage device of the host or an external storage device. The electronic system 1000 may include a solid state disk (SSD), a USB memory, a secure digital (SD) card, a mini secure digital (mSD) card, a micro secure digital (micro SD) card, a secure digital high capacity (SDHC) card, a memory stick card, a smart media (SM) card, a multi-media card (MMC), an embedded multi-media card (eMMC), a compact flash (CF) card, or the like.

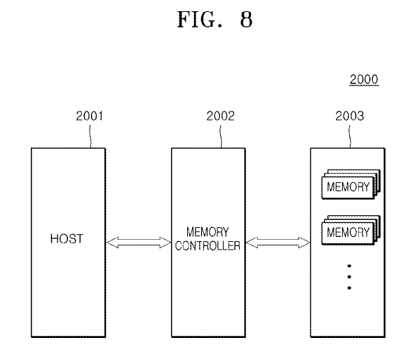

Referring to FIG. 8, an electronic system 2000 according to an embodiment may include a host 2001, a memory controller 2002 and a data storage circuit 2003.

The host 2001 may output a request signal and data to the memory controller 2002 to access the data storage circuit 2003. The memory controller 2002 may supply the data, a data strobe signal, a command, addresses and a clock signal to the data storage circuit 2003 in response to the request signal, and the data storage circuit 2003 may execute a write operation or a read operation in response to the command. The host 2001 may transmit the data to the memory controller 2002 to store the data into the data storage circuit 2003. In addition, the host 2001 may receive the data outputted from the data storage circuit 2003 through the memory controller 2002. The host 2001 may include a circuit that corrects errors of the data using an error correction code (ECC) scheme.

The memory controller 2002 may act as an interface that connects the host 2001 to the data storage circuit 2003 for communication between the host 2001 and the data storage circuit 2003. The memory controller 2002 may receive the request signal and the data outputted from the host 2001 and may generate and supply the data, the data strobe signal, the command, the addresses and the clock signal to the data storage circuit 2003 in order to control operations of the data storage circuit 2003. In addition, the memory controller 2002 may supply the data outputted from the data storage circuit 2003 to the host 2001.

The data storage circuit 2003 may include a plurality of memories. The data storage circuit 2003 may receive the data, the data strobe signal, the command, the addresses and the clock signal from the memory controller 2002 to execute the write operation or the read operation. Each of the memories included in the data storage circuit 2003 may include a circuit that corrects the errors of the data using an error correction code (ECC) scheme. The data storage circuit 2003 may include the second semiconductor device 2 illustrated in FIG. 1.

In some embodiments, the electronic system 2000 may be realized to selectively operate any one of the ECC circuits included in the host 2001 and the data storage circuit 2003. Alternatively, the electronic system 2000 may be realized to simultaneously operate all of the ECC circuits included in the host 2001 and the data storage circuit 2003. The host 2001 and the memory controller 2002 may be realized in a signal chip according to the embodiments. The memory controller 2002 and the data storage circuit 2003 may be realized in a signal chip according to the embodiments.

What is claimed is:

1. A semiconductor system comprising:
a first semiconductor device configured to output commands and addresses and configured to output or receive data; and
a second semiconductor device configured to correct errors of output data to store the corrected output data and the addresses corresponding to the output data having the error if the errors are included in the output data to be outputted as the data while a read operation is performed based on the commands and the addresses and configured to perform an error scrub operation using the corrected and stored output data and the stored addresses during a predetermined operation.

2. The semiconductor system of claim 1, wherein the error scrub operation is not performed if memory cells storing the output data having the error are selected during a write operation.

3. The semiconductor system of claim 1, wherein the error scrub operation is an operation that restores the corrected output data into memory cells selected by the stored addresses.

4. The semiconductor system of claim 1, wherein the second semiconductor device includes:
a control circuit configured to generate an active signal, row addresses, an enablement signal and a column selection signal during the predetermined operation and configured to compare the addresses with latch addresses to generate a selection signal based on a flag signal;
a storage circuit configured to store the output data and the addresses based on the flag signal, configured to output the output data or input data as internal data based on the selection signal, and configured to output the latch addresses or the addresses as column addresses based on the selection signal; and
a memory area configured to detect the errors of the output data to generate the flag signal and configured to store the internal data into memory cells which are located at cross points of a word line selected based on the active signal and the row addresses and bit lines selected based on the enablement signal, the column selection signal and the column addresses.

5. The semiconductor system of claim 4, wherein the flag signal includes a pulse which is created if the output data has the errors.

6. The semiconductor system of claim 4, wherein the latch addresses include information on positions of the memory cells in which the output data having the errors are stored.

7. The semiconductor system of claim 4, wherein the control circuit includes:
an active control circuit configured to generate the row addresses from the addresses and the active signal enabled based on an active command or a pre-charge command; and
an error scrub control circuit configured to generate the enablement signal and the column selection signal from the addresses based on any one of the pre-charge command, a read command and a write command and configured to generate the selection signal which is enabled during a predetermined period based on the flag signal and which is disabled if a combination of the addresses is consistent with a combination of the latch addresses.

8. The semiconductor system of claim 7, wherein the error scrub control circuit includes:
a scrub signal generation circuit configured to generate a scrub signal which is enabled during a predetermined period based on the pre-charge command and the flag signal and which is disabled based on the enablement signal, the column selection signal and a comparison signal;
a read/write control circuit configured to generate the selection signal which is enabled if the scrub signal is enabled based on any one of the pre-charge command, the write command and the read command and configured to generate the enablement signal and the column selection signal according to a combination of the addresses; and
a comparison circuit configured to generate the comparison signal which is enabled if a combination of the addresses consistent with a combination of the latch addresses.

9. The semiconductor system of claim 8, wherein the scrub signal generation circuit includes:
a first logic circuit configured to generate an internal reset signal which is enabled based on the enablement signal, the column selection signal and the comparison signal or based on a delayed scrub signal;
a latch circuit configured to generate a pre-scrub signal which is enabled based on the flag signal and which is disabled based on the internal reset signal or an external reset signal;
a second logic circuit configured to output the pre-scrub signal as the scrub signal based on the pre-charge command; and
a delay circuit configured to delay the scrub signal by a predetermined delay time to generate the delayed scrub signal.

10. The semiconductor system of claim 4, wherein the storage circuit includes:
an address storage circuit configured to latch the addresses to generate the latch addresses based on the flag signal and configured to output the latch addresses or the addresses as the column addresses based on the selection signal; and
a data storage circuit configured to latch the output data to generate latch data based on the flag signal and configured to output the latch data or the input data as the internal data based on the selection signal.

11. The semiconductor system of claim 10, wherein the address storage circuit includes:
a first register configured to latch the addresses to generate the latch addresses based on the flag signal being enabled;
a first multiplexer configured to output the latch addresses as the column addresses based on the selection signal SEL being enabled and configured to output the addresses as the column addresses based on the selection signal SEL being disabled.

12. The semiconductor system of claim 10, wherein the data storage circuit includes:
a second register configured to latch the output data to generate the latch data based on the flag signal being enabled; and
a second multiplexer configured to output the latch data as the internal data based on the selection signal being enabled and configured to output the input data as the internal data based on the selection signal being disabled.

13. The semiconductor system of claim 4, wherein the memory area includes:
a memory cell array configured to include a plurality of memory cells which are respectively located at cross points of a plurality of word lines selected by the active signal and the row addresses and a plurality of bit lines selected by the enablement signal, the column selection signal and the column addresses; and
an error correction circuit configured to detect errors of the internal data stored in the plurality of memory cells during the read operation, configured to correct the errors of the internal data to output the corrected internal data as the output data during the read operation, configured to generate the flag signal which is enabled if the output data include erroneous bits during the read operation, and configured to store the internal data into the plurality of memory cells during the write operation.

14. A semiconductor device comprising:
a control circuit configured to generate an active signal, row addresses, an enablement signal and a column selection signal during a predetermined operation and configured to generate a selection signal based on a flag signal if a combination of latch addresses is consistent with a combination of addresses;
a storage circuit configured to store output data based on the flag signal, configured to latch the addresses to generate the latch addresses based on the flag signal, configured to output the output data as internal data based on the selection signal, and configured to output the latch addresses as column addresses based on the selection signal; and
a memory area configured to detect errors of the output data to generate the flag signal and configured to perform an error scrub operation that stores the internal data into memory cells which are selected by the row addresses and the column addresses based on the active signal, the enablement signal and the column selection signal.

15. The semiconductor device of claim 14, wherein the error scrub operation is an operation that restores the output data generated by correcting the errors into the memory cells selected by the addresses.

16. The semiconductor device of claim 14, wherein the flag signal includes a pulse which is created if the output data has the errors.

17. The semiconductor device of claim 14, wherein the latch addresses include information on positions of the memory cells in which the output data having the errors are stored.

18. The semiconductor device of claim 14, wherein the control circuit includes:
an active control circuit configured to generate the row addresses from the addresses and the active signal enabled based on an active command or a pre-charge command; and
an error scrub control circuit configured to generate the enablement signal and the column selection signal from the addresses based on any one of the pre-charge command, a read command and a write command and configured to generate the selection signal which is enabled during a predetermined period based on the flag signal and which is disabled if a combination of the addresses is consistent with a combination of the latch addresses.

19. The semiconductor device of claim 18, wherein the error scrub control circuit includes:
a scrub signal generation circuit configured to generate a scrub signal which is enabled during a predetermined period based on the pre-charge command and the flag signal and which is disabled based on the enablement signal, the column selection signal and a comparison signal;
a read/write control circuit configured to generate the selection signal which is enabled if the scrub signal is enabled based on any one of the pre-charge command, the write command and the read command and configured to generate the enablement signal and the column selection signal according to a combination of the addresses; and
a comparison circuit configured to generate the comparison signal which is enabled if a combination of the addresses consistent with a combination of the latch addresses.

20. The semiconductor device of claim 19, wherein the scrub signal generation circuit includes:
a first logic circuit configured to generate an internal reset signal which is enabled based on the enablement signal, the column selection signal and the comparison signal or based on a delayed scrub signal;
a latch circuit configured to generate a pre-scrub signal which is enabled based on the flag signal and which is disabled based on the internal reset signal or an external reset signal;
a second logic circuit configured to output the pre-scrub signal as the scrub signal based on the pre-charge command; and
a delay circuit configured to delay the scrub signal by a predetermined delay time to generate the delayed scrub signal.

21. The semiconductor device of claim 14, wherein the storage circuit includes:
an address storage circuit configured to latch the addresses to generate the latch addresses based on the flag signal and configured to output the latch addresses or the addresses as the column addresses based on the selection signal; and
a data storage circuit configured to latch the output data to generate latch data based on the flag signal and configured to output the latch data or input data as the internal data based on the selection signal.

22. A semiconductor system comprising:
a first semiconductor device configured to output commands and addresses and configured to output or receive data; and
a second semiconductor device configured to store addresses of output data having an erroneous bit and the output data in memory cells during a read operation based on the commands and the addresses and perform an error scrub operation restoring the stored output data in the memory cells during a predetermined operation.

23. The semiconductor system of claim 22, wherein the error scrub operation is not performed if memory cells storing the output data having the erroneous bit are selected during a write operation.
